(19) United States
(12) Patent Application Publication
(10) Pub. No.: US 2025/0197193 A1
(43) Pub. Date: Jun. 19, 2025

(54) ANTI-STICTION ELECTRODES

(71) Applicant: InvenSense, Inc., San Jose, CA (US)

(72) Inventors: Roberto Martini, Milano (IT); Matthew Julian Thompson, Beaverton, OR (US); Luca Coronato, Corsico (IT)

(21) Appl. No.: 18/980,825

(22) Filed: Dec. 13, 2024

Related U.S. Application Data
(60) Provisional application No. 63/609,901, filed on Dec. 14, 2023.

(51) Int. Cl. B81B 3/00; G01P 15/125

(52) U.S. Cl. CPC B81B 3/0016; G01P 15/125; B81B 2201/0235; B81B 2203/0163; B81B 2203/04; B81B 2203/051; B81B 2203/056; B81B 2203/058

(57) ABSTRACT

A MEMS accelerometer includes a proof mass that rotates about an in-plane axis in response to a linear acceleration such that a portion of the proof mass moves out of plane along an out-of-plane axis in a direction of a bump stop. When the proof mass becomes stuck to the bump stop, a signal is applied to one or more anti-stiction electrodes in a manner that moves the proof mass along a movement axis in order to release the proof mass from the bump stop.

### CROSS REFERENCE TO RELATED APPLICATION

The present application claims priority to U.S. Provisional Patent Application No. 63/609,901, filed Dec. 14, 2023, and entitled “Electrostatic Stiction Recovery Method via Excitation of Non-Sense Modes,” which is incorporated by reference herein in it its entirety.

### BACKGROUND

Numerous items such as smart phones, smart watches, tablets, automobiles, aerial drones, appliances, aircraft, exercise aids, and game controllers may utilize sensors such as microelectromechanical system (MEMS) sensors during their operation. In many applications, various types of motion sensors such as accelerometers and gyroscopes may be analyzed independently or together in order to determine varied information for particular applications. For example, gyroscopes and accelerometers may be used in gaming applications (e.g., smart phones or game controllers) to capture complex movements by a user, drones and other aircraft may determine orientation based on gyroscope measurements (e.g., roll, pitch, and yaw), and vehicles may utilize measurements for determining direction (e.g., for dead reckoning) and safety (e.g., to recognizing skid or roll-over conditions).

A MEMS sensor such as a MEMS accelerometer includes a proof mass that moves in response to a force of interest such as linear acceleration in a particular direction. The movement of the proof mass in response to the linear acceleration is measured, e.g., by sense electrodes that are located at a fixed position relative to the proof mass. The MEMS accelerometer may include bump stops that prevent excessive movements of the proof mass such as due to dropping or other shocks that could otherwise cause damage to the proof mass, sense electrodes, or other electrical or mechanical components of the MEMS accelerometer. In some instances, due to “stiction” forces the proof mass may become stuck to the bump stop such that it does not release from the bump stop even in response to a linear acceleration in the sense direction.

### SUMMARY

In an embodiment, a microelectromechanical system (MEMS) accelerometer comprises a suspended spring-mass system comprising a proof mass, wherein the proof mass moves in a first mode along a first axis in response to an external linear acceleration, and a bump stop located below the proof mass along the first axis, wherein the proof mass is capable of moving along the first axis to contact and stick to the bump stop. The MEMS accelerometer can also comprise an anti-stiction electrode located adjacent to the proof mass that actuates the proof mass in a second mode along a second axis that is non-parallel to the first axis and processing circuitry configured to determine that the proof mass is stuck to the bump stop and to apply a signal to the anti-stiction electrode to cause a movement of the proof mass in the second mode at least until the proof mass releases from the bump stop.

In an embodiment, a method of releasing a proof mass of microelectromechanical system (MEMS) accelerometer from a bump stop comprises determining, by processing circuitry, that a proof mass is stuck to a bump stop. The proof mass moves in a first mode in response to a linear acceleration in a direction of a first axis, the bump stop is located below the proof mass in along the first axis, and the proof mass is capable of moving along the first axis to contact and stick to the bump stop. The method also comprises applying, by the processing circuitry in response to the determination that the proof mass is stuck to the bump stop, a signal to an anti-stiction electrode to cause a movement of the proof mass in a second mode at least until the proof mass releases from the bump stop. The anti-stiction electrode is located adjacent to the proof mass at a location to cause a movement of the proof mass in the second mode about a second axis that is non-parallel to the first axis when the proof mass is actuated by the anti-stiction electrode.

In an embodiment, a microelectromechanical system (MEMS) accelerometer comprises a suspended spring-mass system comprising a proof mass, wherein the proof mass moves about a first axis in response to an external linear acceleration and in a direction of a second axis that is out-of-plane from the suspended spring mass system in response to the linear acceleration. The MEMS accelerometer can also comprise a bump stop located below the proof mass along the second axis, wherein the proof mass is capable of moving along the second axis to contact and stick to the bump stop, and an anti-stiction electrode located adjacent to the proof mass that actuates the proof mass in a second mode along a third axis that is non-parallel to the first axis and the second axis. The MEMS accelerometer can also comprise processing circuitry configured to determine that the proof mass is stuck to the bump stop and to apply a signal to the anti-stiction electrode to cause a movement of the proof mass in the second mode at least until the proof mass releases from the bump stop.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative MEMS system in accordance with an embodiment of the present disclosure;

FIG. 2 depicts a top view of a MEMS accelerometer including out-of-plane anti-stiction electrodes in accordance with an embodiment of the present disclosure;

FIG. 3 depicts a top view of a MEMS accelerometer including a second configuration of out-of-plane anti-stiction electrodes in accordance with another embodiment of the present disclosure;

FIG. 4 depicts a top view of a MEMS accelerometer including in-plane anti-stiction electrodes in accordance with another embodiment of the present disclosure;

FIG. 5 depicts a top view of a MEMS accelerometer including a second configuration of in-plane anti-stiction electrodes in accordance with another embodiment of the present disclosure;

FIG. 6 depicts a top view of a MEMS accelerometer including a third configuration of in-plane anti-stiction electrodes in accordance with another embodiment of the present disclosure;

FIG. 7 depicts a top view of bump stops with exemplary shapes in accordance with an embodiment of the present disclosure; and

FIG. 8 depicts exemplary steps of a method of releasing a stuck proof mass from a bump stop in accordance with an embodiment of the present disclosure.

### DETAILED DESCRIPTION

A MEMS sensor such as a MEMS accelerometer includes one or more proof masses that are suspended within a spring-mass system of a MEMS layer to move in response to a particular force of interest such as a linear acceleration. Large forces such as shock forces may cause large movements of the proof mass that could damage the proof mass, other components of the suspended spring mass system such as springs, or adjacent sense electrodes and circuitry. In order to avoid these movements, bump stops are positioned adjacent to the proof mass to prevent the full range of motion of the proof mass in response to such large forces. In some instances, while the bump stop may prevent the full range of motion of the proof mass with respect to other components, the proof mass becomes stuck to the bump stop along an axis of contact between the bump stop and the proof mass. The natural restoring forces of the spring-mass system such as via springs coupled to the proof mass may be inadequate to return the proof mass to its normal functional position.

Anti-stiction electrodes may be located adjacent to the proof mass to impart forces on the proof mass that assist in releasing the proof mass from the bump stop. The stiction force generally is exerted along mating faces of bump stop and proof mass, such that forces along the contact axis of the bump stop have to overcome the entire stiction force to have even partial release of the proof mass. The anti-stiction electrodes and bump stop may be located, sized, and positioned such that the forces applied to the proof mass by the anti-stiction electrodes are not along the contact axes or parallel to the contact axis, and in some embodiments, are also not perpendicular to the contact axis. As a result, the forces imparted by the anti-stiction electrodes partially lift or release the proof mass from the anti-stiction electrode, reducing the force required for the combined force of the anti-stiction electrodes and restoring springs to return the proof mass to its normal functional position.

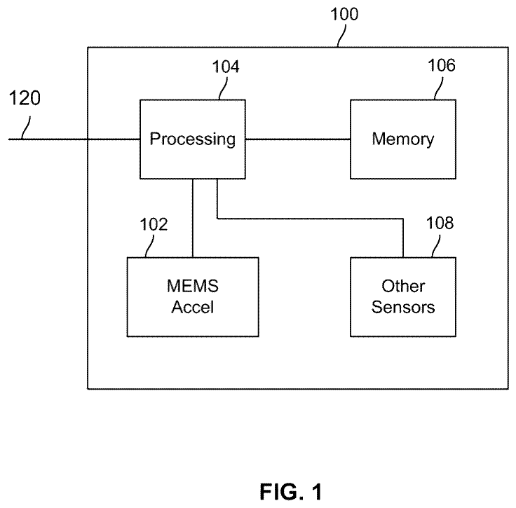

FIG. 1 shows an illustrative MEMS system 100 in accordance with an embodiment of the present disclosure. Although particular components are depicted in FIG. 1, it will be understood that other suitable combinations of the MEMS, processing components, memory, and other circuitry may be utilized as necessary for different applications and systems. In accordance with the present disclosure, the MEMS system may include a MEMS accelerometer 102 as well as additional sensors 108. Although the present disclosure will be described in the context of signals received from MEMS accelerometers and out-of-plane bump stops, it will be understood that the anti-stiction of the present disclosure may be utilized with a variety of MEMS sensor types that include bump stops (e.g., MEMS gyroscopes, pressure sensors, etc.) as well as other bump stop configurations (e.g., in-plane bump stops).

Processing circuitry 104 may include one or more components providing processing based on the requirements of the MEMS system 100. In some embodiments, processing circuitry 104 may include hardware control logic that may be integrated within a chip of a sensor (e.g., on a base substrate of a MEMS accelerometer 102 or other sensors 108, or on an adjacent portion of a chip to the MEMS accelerometer 102 or other sensors 108) to control the operation of the MEMS accelerometer 102 or other sensors 108 and perform aspects of processing for the MEMS accelerometer 102 or the other sensors 108. In some embodiments, the MEMS accelerometer 102 and other sensors 108 may include one or more registers that allow aspects of the operation of hardware control logic to be modified (e.g., by modifying a value of a register). In some embodiments, processing circuitry 104 may also include a processor such as a microprocessor that executes software instructions, e.g., that are stored in memory 106. The microprocessor may control the operation of the MEMS accelerometer 102 by interacting with the hardware control logic and processing signals received from MEMS accelerometer 102. The microprocessor may interact with other sensors 108 in a similar manner. In some embodiments, some or all of the functions of the processing circuitry 104, and in some embodiments, of memory 106, may be implemented on an application specific integrated circuit (“ASIC”) and/or a field programmable gate array (“FPGA”).

Although in some embodiments (not depicted in FIG. 1), the MEMS accelerometer 102 or other sensors 108 may communicate directly with external circuitry (e.g., via a serial bus or direct connection to sensor outputs and control inputs), in an embodiment the processing circuitry 104 may process data received from the MEMS accelerometer 102 and other sensors 108 and communicate with external components via a communication interface 110 (e.g., a serial peripheral interface (SPI) or I2C bus, in automotive applications a controller area network (CAN) or Local Interconnect Network (LIN) bus, or in other applications a suitably wired or wireless communications interface as is known in the art). The processing circuitry 104 may convert signals received from the MEMS accelerometer 102 and other sensors 108 into appropriate measurement units (e.g., based on settings provided by other computing units communicating over the communication interface 110) and perform more complex processing to determine measurements such as orientation or Euler angles, and in some embodiments, to determine from sensor data whether a particular activity (e.g., walking, running, braking, skidding, rolling, etc.) is taking place. In some embodiments, some or all of the conversions or calculations may take place on the hardware control logic or other on-chip processing of the MEMS accelerometer 102 or other sensors 108.

In some embodiments, certain types of information may be determined based on data from multiple MEMS gyroscopes 102 and other sensors 108 in a process that may be referred to as sensor fusion. By combining information from a variety of sensors it may be possible to accurately determine information that is useful in a variety of applications, such as image stabilization, navigation systems, automotive controls and safety, dead reckoning, remote control and gaming devices, activity sensors, 3-dimenstional cameras, industrial automation, and numerous other applications.

In embodiments of the present disclosure, a proof mass of a MEMS sensor (e.g., an accelerometer) moves out-of-plane in response to a force (e.g., linear acceleration) that is in an out-of-plane (e.g., x-axis) direction. If the movement is large enough, the proof mass comes into contact with a bump stop located in a plane above or below the proof mass and the proof mass and bump stop become stuck to each other where their surfaces contact (e.g., due to stiction forces). The axis along which the proof mass contacts the bump stop defines a first axis. Anti-stiction electrodes are located adjacent to the proof mass and apply a force to the proof mass directly (e.g., to the proof mass) or indirectly (e.g., via other movable components connected to the proof mass, not depicted herein). Rather than attempting to move the proof mass directly along the first axis, the proof mass is moved along and about axes that are non-parallel to the first axis, and in some embodiments, that are also non-perpendicular to the proof mass. As a result, the entire stiction force associated with the touching surfaces does not need to be overcome in one motion or movement, but rather, can be overcome via less applied force while allowing other forces such as stored torsional forces in sense springs and/or repeated application of the anti-stiction forces (e.g., a “rocking” motion) to release the proof mass from the bump stop.

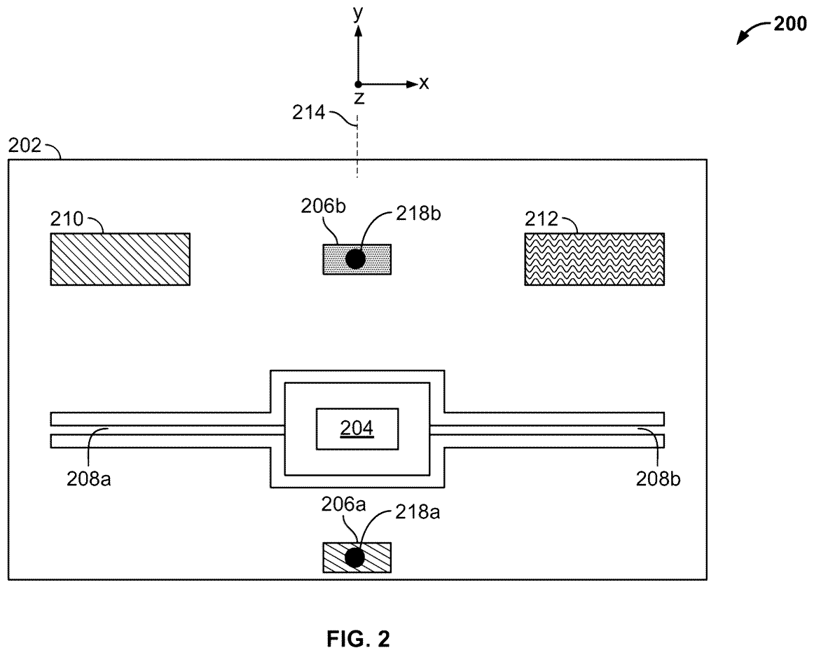

FIG. 2 depicts a top view of a MEMS accelerometer 200 including out-of-plane anti-stiction electrodes in accordance with an embodiment of the present disclosure. MEMS accelerometer 200 may have a number of different configurations and components. In an exemplary embodiment, the MEMS accelerometer 200 includes a proof mass 202 within a MEMS layer defining upper and lower MMES planes, that in turn is supported by an anchor 204. It will be understood that the particular configuration, shape, size, and the like of the illustrated MEMS accelerometers herein (e.g., in FIGS. 2-6) are depicted for illustration only, and that the present disclosure may similarly be applied to other MEMS accelerometers configurations, shapes, and sizes, as well as to other MEMS sensors such as gyroscopes, pressure sensors, and microphones. In the embodiments depicted in FIGS. 2-6, components that are normally located in the MEMS layer (e.g., in plane) are depicted without shading or cross-hatching, while components that are normally located outside of the MEMS layer (e.g., out of plane) are depicted with shading and cross-hatching. For example, in FIG. 2 the depicted proof mass 202, anchor 204, and sense springs 208a and 208b are normally located within the MEMS (e.g., with the proof mass 202 capable of rotating out of plane about senses springs 208a and 208b in response to a z-axis linear acceleration) while the bump stops 206a and 206b and anti-stiction electrodes 210 and 212 are located below the MEMS layer, for example, on a base substrate layer including processing circuitry such as CMOS processing circuitry.

While only one proof mass 202 is depicted within FIG. 2., any number of proof masses 202 may be included within a single MEMS accelerometer 200 (e.g., one for each spatial axis), in some cases each with their own unique geometry, design, support structures, thickness, and configuration. The proof mass 202 may move upon the application of an external force to the system. The direction of movement (x, y, or z-axis) is dependent on the configuration of the MEMS accelerometer 200, the direction of the applied force, and how the proof mass 202 is positioned within the device. For example, in the configuration of FIG. 2 the proof mass is designed and suspended to be responsive to z-axis linear accelerations. In cases where the external force is large, an extreme movement of the proof mass 202 may occur that risks collision of the proof mass 202 with other components. Therefore, bump stops 206 may be present within the MEMS accelerometer 200 and may impede and/or dampen kinetic force in order to protect both the proof mass 202 and other components of the device. There may be one or multiple sense springs 208 that suspend the proof mass 202 in its own spatial plane and provide a restoring force to return the proof mass 202 back to a resting position once the external force has been removed. In some embodiments the proof mass 202 may also be supported by one or multiple anchors 204. The change in location (i.e., the amount of movement) of the proof mass 202 within the MEMS accelerometer 200 may be determined using one or more sensors (not shown) that are capable of measuring changes in a particular value (e.g., capacitance, inductance, resistance).

The anchor 204 may be a fixed, immovable structure on the base substrate layer and/or lid/handle layer (not shown) that acts as a rigid attachment point for the proof mass 202 (or other device components), thus allowing it to have controlled and predictable movements once an external force is applied to the system. The anchor 204 also serves to provide rigidity and structural integrity to the entire MEMS accelerometer 200. While only one anchor 204 is depicted within FIG. 2, any number of anchors 204 may be included within a single MEMS accelerometer 200, in at least some cases each with their own unique geometry (e.g., plate, beam), design, material, thickness, and configuration.

Bump stops 206 may be present on the base substrate, and may reduce a likelihood of the proof mass 202 moving beyond a point where damage or breakage could occur to the proof mass or other components (e.g., sense electrodes, etc.). Additionally, bump stops 206 may protect other MEMS components within the device from sudden collisions caused by extreme external forces. While the bump stops 206 may generally made from the same material as other components on the MEMS accelerometer 200, they may contain additives or coating to make them relatively more elastic, and thus better able to absorb sudden bursts of kinetic energy. After a collision between the proof mass 202 and bump stop 206 along an axis (e.g., axis 218a or axis 218b), a stiction force between surfaces of a bump stop 206 and proof mass 202 may delay or fully prevent the proof mass 202 from returning to its resting position (as will be discussed further below). In some embodiments multiple bump stops may be provided in various locations across the MEMS device. For example, a tail bump stop 206a may be positioned in a parallel plane towards the lower portion of the proof mass 202, and a head bump stop 206b may be positioned in a parallel plane towards the upper portion of the proof mass 202. Such a configuration allows for protection of the proof mass 202 in both movement directions (e.g., about the axis of the sense springs 208a and 208b, in the direction of one of bump stops 206a and 206b along one of axes 218a or 218b). In some cases, multiple bump stops 206 can distribute external forces across a larger surface area (i.e., several bump stops for a single movement direction), thus reducing the kinetic energy a single bump stop 206 would need to absorb to prevent damage. The size, location, design, and shape of the bump stops 206 can vary within a single MEMS accelerometer 200.

MEMS accelerometer 200 also includes sense springs 208a and 208b that suspend the proof mass 202 from the anchor 204 and facilitate movement of the proof mass 202 in response to external forces. The geometry, number, thickness, and general configuration of the sense springs 208 may vary for different MEMS accelerometers 200 designs depending on a multitude of considerations (e.g., movement direction of the proof mass 202) as is known in the art. Each sense spring 208 has a respective spring constant that determines not only the strength of its restoring force, but also the sensitivity and operational range of the MEMS accelerometer 200. Stiffer springs can better withstand larger external forces and may be received in accelerometers that require wide measurements ranges. Conversely, more flexible springs generally allow for greater displacement of the proof mass 202, thus increasing the sensitivity of the device. After an external force causes the proof mass 202 to move in one direction, the restoring force of the sense spring 208 biases the proof mass 202 in the opposite direction. If a strong stiction force exists (e.g., between the proof mass 202 and bump stop 206), then the restoring force of the sense springs 208 may not be sufficient to return the proof mass 202 to its resting position. In that case, the MEMS accelerometer 200 is unable to properly function until the proof mass 202 is restored to its original state.

In an embodiment, the proof mass 202 may move along the z-axis. To prevent the proof mass 202 from colliding with the substrate or other components, a combination of a head bump stop 206a and a tail bump stop 206b that are located in a lower parallel plane may be utilized. Sense springs 208a and 208b assist in suspending the proof mass 202 within the accelerometer and are generally capable of returning the proof mass 202 back to its resting state after an external force is applied based on torsional forces created within the sense springs 208 and 208b when the proof mass rotates about those springs and moves in the z-axis direction (e.g., an upper side of the proof mass 202 located above bump stop 206b moves towards or away from bump stop 206b along axis 218b while a lower side of the proof mass 202 located above bump stops 206a moves towards or away from bump stop 206a along axis 218a, based on the direction of the linear acceleration).

If the external force causes a collision between the proof mass 202 and one of the bump stops 206a or 206b of a sufficient magnitude along an axis 218, stiction forces may prevent the surface of the proof mass 202 from detaching from the bump stop 206a or 206b, and thus inhibit the proof mass 202 returning to its resting position within the MEMS layer solely based on the restoring forces of sense springs 208a and 208b. In such cases, a left anti-stiction electrode 210 and a right anti-stiction electrode 212 may be employed to facilitate the detachment of the proof mass 202 from the bump stop 206a or 206b. In the embodiment of FIG. 2, the configuration of the anti-stiction electrodes in FIG. 2 is such that they are in a plane below the proof mass 202 and are located on the same lateral edges of the MEMS accelerometer 200, but at different x-positions along it. Upon applying a pre-determined signal pattern to the anti-stiction electrodes 210 and/or 212, an out-of-plane torsional force about axis 214 is exerted onto the proof mass 202 to overcome the stiction forces, thus dislodging the proof mass 202 from the bump stop(s) 206, and returning the proof mass 202 to its resting position.

Anti-stiction electrodes thus facilitate the restoration of the proof mass 202 back to its resting state in the event that the stiction forces are greater than the restoration force of the sense springs 208. Upon application of a potential to the anti-stiction electrodes, an electrostatic force is produced that can affect the proof mass 202 (e.g., electrostatic repulsion/attraction). The geometry, number, polarity, location, material, coating, and general configuration of the anti-stiction electrodes may vary across MEMS accelerometers 200, and may have a direct impact on the magnitude of force applied to the stuck proof mass 202. In the depicted embodiment of FIG. 2, there is a first anti-stiction electrode 210 and a second anti-stiction electrode 212 that are fixed to the substrate and work together in order to release a proof mass 202 that may be stuck to one or both bump stops 206. If an opposite potential is applied to the first anti-stiction electrode 210 and the second anti-stiction electrode 212, an out-of-plane torsional force will be applied to the proof mass 202 where it can rotate about a rotational axis 214. The applied polarities may be reversed in order to have the out-of-plane torsional force rotate the proof mass 202 around the same rotational axis 214, but in the reverse (clockwise) direction. The combination of the restoration force from the sense spring 208 and the electrostatic force from the anti-stiction electrodes overcomes the stiction force and allow the proof mass 202 to return to its resting position.

A variety of signals and signal patterns may be applied to the anti-stiction electrodes. For example, a continuous or discrete periodic chirp signal may be used to transmit a characteristic signal with a defined polarity to the anti-stiction electrodes, whereby a rapid and alternating polarity may be applied to the first anti-stiction electrode 210 and the second anti-stiction electrode 212, thus achieving a rocking motion of the proof mass 202 about the rotational axis 214. The characteristics (e.g., frequency range, duty cycle, amplitude, duration) of the chirp signal can be modified to induce different effects on the proof mass 202 (e.g., rate and direction of rotation).

As is depicted in FIG. 2, anti-stiction electrode 210 and anti-stiction electrode 212 do not simultaneously apply the same-signed potential (i.e., positive or negative) in an attempt to move the proof mass 202 vertically along the z-axis parallel to axis 218, but rather apply forces that cause a rotation about an axis that is not parallel to axis 218, as depicted for by axis 214. For example, the anti-stiction electrode 210 and anti-stiction electrode 212 may apply a signal pattern in an equal and oppositive manner to create a rocking motion about axis 214. The rocking motion serves to release portions of the proof mass from the bump stop rather than attempting to overcome the entire stiction force as would occur with a force along or parallel to axis 218. Although particular respective locations and numbers of anti-striction electrodes and bump stops are depicted in FIGS. 2-6 herein, it will be understood that a variety of locations and numbers of anti-stiction electrodes and bump stops may be utilized in accordance with the present disclosure to apply non-parallel (and in some embodiments, non-parallel and non-perpendicular) movements to the proof mass to facilitate a partial lifting or separation of the proof mass from the bump stop rather than attempting to overcome the stiction force along the bump stop contact axis 218 via parallel movements of proof 202.

Sensors and processing circuitry (not shown) that is integrated onto the substrate and/or bump stops 206 may determine if the proof mass 202 is still stuck onto the bump stops 206 or if the proof mass 202 has been released. Once the sensor determines the release of the proof mass 202 from the bump stop 206 (e.g., change in output threshold signal), the first anti-stiction electrode 210 and to the second anti-stiction electrode 212 may be inactivated.

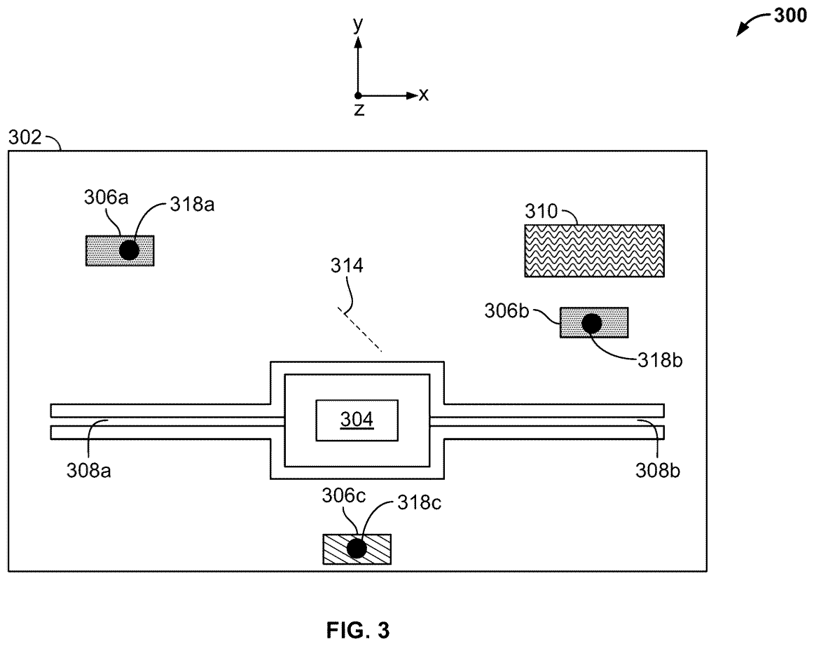

FIG. 3 depicts a top view of a MEMS accelerometer 300 including a second configuration of out-of-plane anti-stiction electrodes in accordance with another embodiment of the present disclosure. MEMS accelerometer 300 is similar to and functions in a similar manner as that of the MEMS accelerometer 200. However, the bump stops 306 and anti-stiction electrode 310 are positioned in such a way to alter the interaction with, and the effects on, the proof mass 302. The tail bump stop 306c remains in a parallel plane towards the bottom lateral edge of the proof mass 302, but the head bump stop 306a shifts in a parallel plane towards the corner of the proof mass 302 and an additional secondary bump stop 306b is added in a parallel plane near the single anti-stiction electrode 310 to limit the displacement of the proof mass 302 once it is released from the stuck bumpstop. Upon applying a pre-determined potential to the anti-stiction electrode 310, an out-of-plane torsional force about the rotational axis 314 is exerted onto the proof mass 302. As depicted in FIG. 3, the rotational axis 314 is neither parallel to nor perpendicular to any of the axes of contact (e.g., axis 318a for bump stop 306a, axis 318b for bump stop 306b, and axis 318c for bump stop 306c) between the proof mass 302 and the bump stops 306a, 306b, and 306c. Accordingly the force applied to the proof mass 302 by anti-stiction electrode 310 will tend to lift the proof mass 302 along portions of the bump stops 306, reducing the force required to obtain at least partial separation of the proof mass from one or more of the bump stops 306 and allowing the restoring force of the sense springs 308a to 308b to overcome the stiction force.

In this particular MEMS accelerometer 300 configuration, there exists only one anti-stiction electrode 310. When the proof mass 302 is stuck to one or multiple bump stops 306 within the device, a signal can be applied to the single anti-stiction electrode 310. Similar to the device of FIG. 2, a continuous or discrete periodic chirp signal may be used to transmit a characteristic signal with a defined polarity to the anti-stiction electrode 310, whereby a rapid and alternating polarity may be applied, thus achieving a twisting motion of the proof mass 302 about the rotational axis 314. The rotational axis 314 is offset from the plane of symmetry of the proof mass 302, indicating that a non-linear torsional force would be applied. Instead of the torsional force eliciting a rocking motion about a central axis of the MEMS accelerometer (as was the case in FIG. 2 where a dual anti-stiction electrode system was utilized), the offset position of the anti-stiction electrode 310 causes an out-of-plane rocking motion about rotational axis 314. Depending on the polarity of the applied potential, there may be a counter-clockwise direction of rotation 314, or a clockwise direction of rotation. The magnitude and linearity of the torsional force applied to the proof mass 302, as well as its angular displacement, can be altered by varying the spatial location of the single anti-stiction electrode 310 across the substrate within the MEMS accelerometer 300.

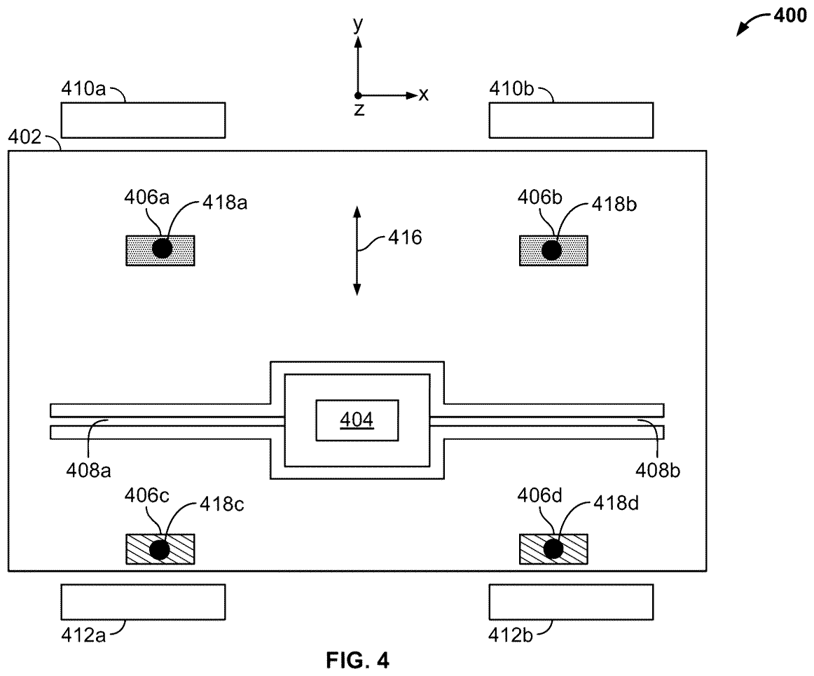

FIG. 4 depicts a top view of a MEMS accelerometer 400 including in-plane anti-stiction electrodes in accordance with another embodiment of the present disclosure. MEMS accelerometer 400 is similar to and functions in a similar manner as that of the MEMS accelerometer 200 and 300. However, the bump stops 406, head anti-stiction electrodes 410, and tail anti-stiction electrodes 412 are positioned in such a way to alter the interaction with, and the effects on, the proof mass 402. The primary head bump stop 406a and primary head bump stop 406b are located below the top half of the proof mass 402 in a parallel plane equidistant from its edges. Similarly, the primary tail bump stop 406c and primary tail bump stop 406d are located below the bottom half of the proof mass 402 in a parallel plane equidistant from its edges. Instead of being in a parallel plane below the proof mass 402, both the head anti-stiction electrodes 410 and tail anti-stiction electrodes 412 are located within the same plane. Upon applying a pre-determined potential to the head anti-stiction electrodes 410 and tail anti-stiction electrodes 412, an in-plane electrostatic force in direction 416 is exerted onto the proof mass 402 that clicits a translational back-and-forth movement that may be able to overcome the stiction forces, thus dislodging it from any bump stops 406 that it may be stuck to and returning it to its resting position.

The numbered elements of FIG. 4 are similar to and function in a similar manner as the components of FIGS. 2-3. However, there is a primary head bump stop 406a and a primary head bump stop 406b that are located in a parallel plane below the proof mass 402, and where both are positioned equidistant from the edges of the proof mass 402. There is also a primary tail bump stop 406c and a primary tail bump stop 406d that are located in a parallel plane below the proof mass 402, and where both are positioned equidistant from the edges of the proof mass 402.

In this particular MEMS accelerometer 400 configuration, there exists two head anti-stiction electrodes 410 and two tail anti-stiction electrodes 412 that are located within the same plane as the proof mass and positioned at the top portion (head) and lower portion (tail) of the proof mass 402, respectively. When the proof mass 402 is stuck to one or multiple bump stops 406 within the device, a potential can be applied to the head anti-stiction electrodes 410 and tail anti-stiction electrodes 412. Similar to the device in FIGS. 2-3, a continuous or discrete periodic chirp signal may be used to transmit a characteristic signal with a defined polarity to the head anti-stiction electrodes 410 and tail anti-stiction electrodes 412, whereby a rapid and alternating polarity may be applied, thus achieving an in-plane translational motion in direction 416 of the proof mass 402 that is not along, in parallel with, or perpendicular (e.g., intersecting in plane) with any of axes of contact 418a, 418b, 418c, and 418d. A back-and-forth translational motion may be achieved with chirp signals comprising particular characteristics. Instead of the electrostatic force eliciting an out-of-plane rotation (as was the case in FIGS. 2-3), it rather induces an in-plane translational motion of the proof mass 402 along axis 416. The magnitude of the electrostatic force applied to the proof mass 402 may be altered by varying which of the head anti-stiction electrodes 410 or tail anti-stiction electrodes 412 receives a particular chirp signal, in addition to altering their locations along the top and bottom lateral edges of the proof mass 402.

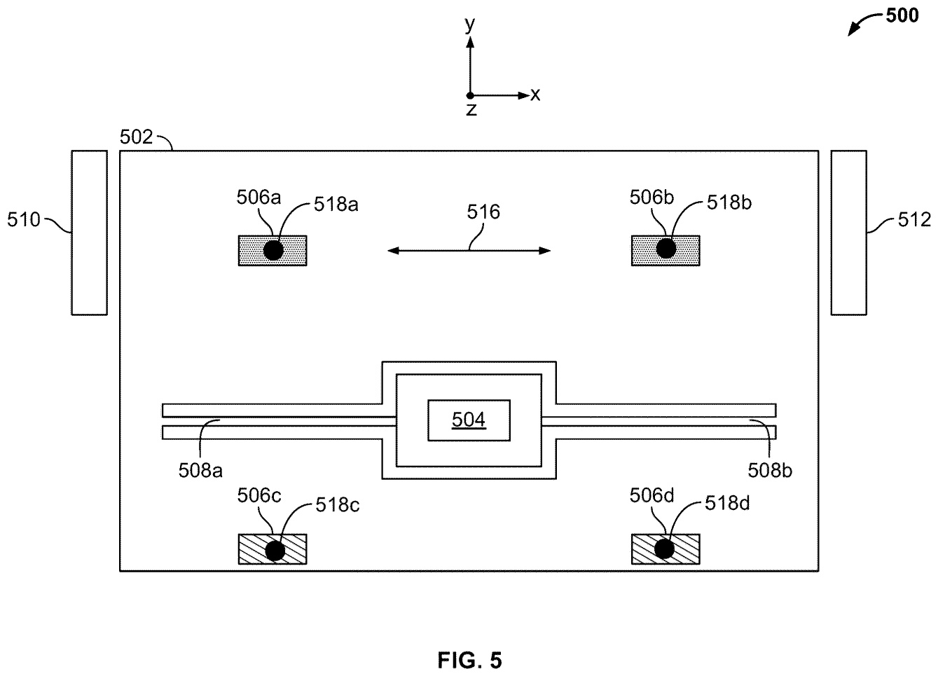

FIG. 5 depicts a top view of a MEMS accelerometer 500 including a second configuration of in-plane anti-stiction electrodes in accordance with another embodiment of the present disclosure. MEMS accelerometer 500 is similar to and functions in a similar manner as that of the MEMS accelerometer 400. However, the first anti-stiction electrode 510 and second anti-stiction electrode 512 are positioned in such a way to alter the interaction with, and the effects on, the proof mass 502. The first anti-stiction electrode 510 and second anti-stiction electrode 512 are located within the same plane as the proof mass 502 along its left and right lateral edges, respectively. Upon applying a pre-determined potential to the first anti-stiction electrode 510 and the second anti-stiction electrode 512, an in-plane electrostatic force in direction 516 is exerted onto the proof mass 502 that elicits a translational side-to-side movement that may be able to overcome the stiction forces, thus dislodging it from any bump stops 506 that it may be stuck to and returning it to its resting position.

The numbered elements of FIG. 5 are similar to and function in a similar manner as the components of FIG. 4. However, there exists a first anti-stiction electrode 510 and a second anti-stiction electrode 512 that are located within the same plane as the proof mass and positioned on the left and right lateral edges of the proof mass 502, respectively. When the proof mass 502 is stuck to one or multiple bump stops 506 within the device, a potential can be applied to the first anti-stiction electrode 510 and second anti-stiction electrode 512. Similar to the device in FIG. 4, a continuous or discrete periodic chirp signal may be used to transmit a characteristic signal with a defined polarity to the first anti-stiction electrode 510 and second anti-stiction electrode 512, whereby a rapid and alternating polarity may be applied, thus achieving an in-plane translational motion in direction 516 of the proof mass 502 that is not along, in parallel with, or perpendicular (e.g., intersecting in plane, at least with respect to bump stops 506c and 506d) with any of axes of contact 518a, 518b, 518c, and 518d. A side-to-side translational motion may be achieved with chirp signals comprising of particular characteristics. The magnitude of the electrostatic force applied to the proof mass 502 may be altered by varying whether the first anti-stiction electrode 510 or the second anti-stiction electrode 512 receives a particular chirp signal, in addition to altering their locations along the left and right lateral edges of the proof mass 502.

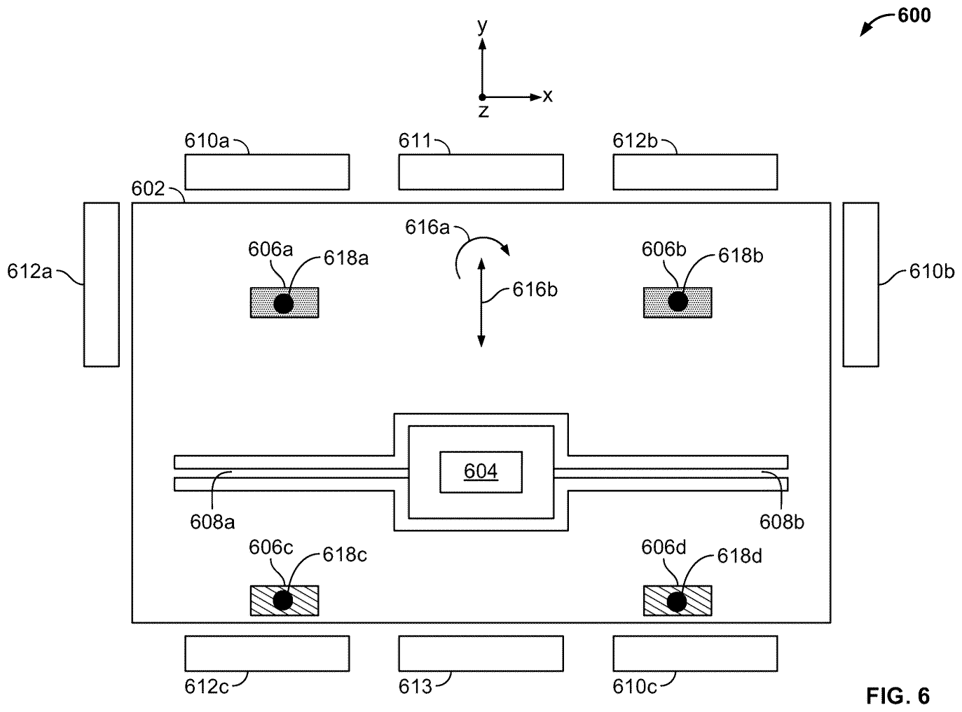

FIG. 6 depicts a top view of a MEMS accelerometer 600 including a third configuration of in-plane anti-stiction electrodes in accordance with another embodiment of the present disclosure. MEMS accelerometer 600 is similar to and functions in a similar manner as that of the MEMS accelerometers 400 and 500. However, the head anti-stiction electrode 611, tail anti-stiction electrode 613, first triplet of anti-stiction electrodes 610, and second triplet of anti-stiction electrodes 612 are positioned in such a way to alter the interaction with, and the effects on, the proof mass 602. A first triplet of anti-stiction electrodes 610 is placed such that one is located on the top, right, and bottom lateral edges of the proof mass 602. A single head anti-stiction electrode 611 and tail anti-stiction electrode 613 are located at the middle on the top and bottom lateral edges of the proof mass 602, respectively. Finally, a second triplet of anti-stiction electrodes 612 is placed such that one is located on the left, top, and bottom lateral edges of the proof mass 602. Similar to FIG, 4, upon applying a pre-determined potential to the head anti-stiction electrode 611 and the tail anti-stiction electrode 613, an in-plane electrostatic force in a direction 616b is exerted onto the proof mass 602 that elicits a translational back-and-forth movement that may be able to overcome the stiction forces, thus dislodging it from any bump stops 606 that it may be stuck to and returning it to its resting position. The addition of the first triplet of anti-stiction electrodes 610 and second triplet of anti-stiction electrodes 612 in MEMS accelerometer 600 configuration allows for an additional force to be applied to the proof mass 602. Through the activation of both the first triplet of anti-stiction electrodes 610 and second triplet of anti-stiction electrodes 612, an in-plane torsional force around a rotational axis in a direction 616a is exerted onto the proof mass 602 that may be able to dislodge it from any bump stops 606 that it may be stuck to.

The numbered elements of FIG. 6 are similar to and function in a similar manner as the components of FIG. 4. However, there is only a single head anti-stiction electrode 611 and tail anti-stiction electrode 613, which are located at the middle on the top and bottom lateral edges of the proof mass 602, respectively. Similar to the functionality of the accelerometer in FIG. 4, a continuous or discrete periodic chirp signal may be used to transmit a characteristic signal with a defined polarity to the head anti-stiction electrode 611 and tail anti-stiction electrode 613, whereby a rapid and alternating polarity may be applied, thus achieving an in-plane translational motion of the proof mass 602 in a direction 616b. A back-and-forth translational motion, in addition to the magnitude of the applied electrostatic force, may be achieved with chirp signals comprising of particular characteristics.

The MEMS accelerometer 600 includes the presence of two triplet anti-stiction electrode systems. A first triplet of anti-stiction electrodes 610 are placed such that one is located on the top, right, and bottom lateral edges of the proof mass 602. A second triplet of anti-stiction electrodes 612 are placed such that one is located on the left, top, and bottom lateral edges of the proof mass 602. Simultaneous activation of the first triplet of anti-stiction electrodes 610 and second triplet of anti-stiction electrodes 613 using a particular chirp signal will exert an in-plane torsional force around a rotational axis in a direction 616a onto the proof mass 602 that may be able to dislodge it from any bump stops 606 that it may be stuck to. Depending on the polarity of the applied potential, there may be a counter-clockwise direction of rotation or a clockwise direction of rotation 616a. While in this embodiment the characteristics of the chirp signal transmitted to each anti-stiction electrode within a particular triplet is the same, other embodiments may vary the chirp signal even within the same triplet to achieve alternative effects on the proof mass 602. Further, the magnitude of the electrostatic force applied to the proof mass 602 may be altered by varying which anti-stiction electrode receives a particular chirp signal, in addition to altering the locations of the anti-stiction electrodes along the left and right lateral edges of the proof mass 602. Collectively and individually, the applied forces along direction 616b and about the axis of 616a are not along, in parallel with, or perpendicular (e.g., intersecting in plane) with any of axes of contact 618a, 618b, 618c, and 618d.

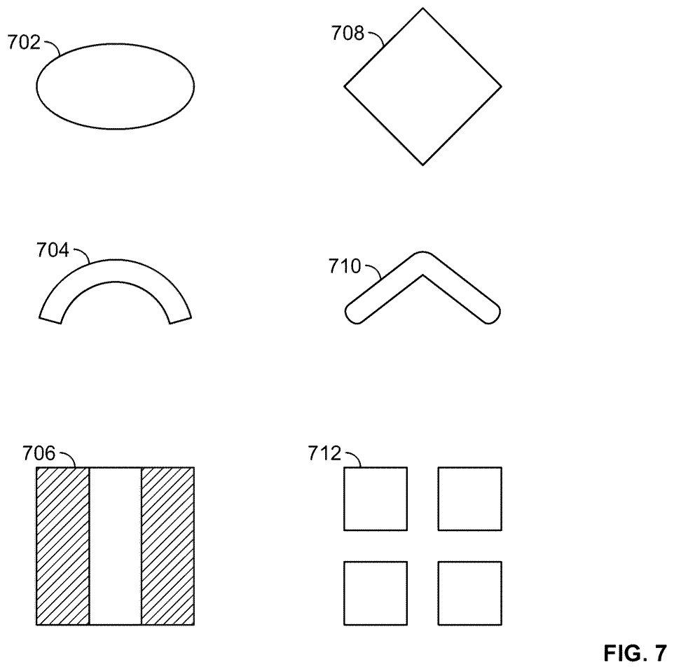

FIG. 7 depicts a top view of bump stops with exemplary shapes in accordance with an embodiment of the present disclosure. In some embodiments, bump stop design, size, location, and orientation may be utilized with the non-parallel and/or non-perpendicular application of release forces by anti-stiction electrodes to further facilitate release of proof masses from bump stops. For example, reducing this stiction force may be possible by modifying the size and geometry of the bump stop. Instead of rectangular bump stops, ovular bump stops 702 and diamond-shaped bump stops 708 may be employed, providing for “lift” surfaces that the release forces can utilize to dislodge at least a portion of the proof mass form the bump stops. Bump stops with varying topographies may be utilized as well, such as rectangular-notched bump stops 706 or square-arrayed bump stops 712. Other examples of bump stops may also be arch-shaped 704 or chevron-shaped with rounded corners 710. It is understood that bump stops may have a number of different configurations and geometries that may best reduce any stiction forces within a given accelerometer design.

Accordingly characteristics of bump stops that may be modified in order to reduce the stiction force include their shape and geometry. As the contact area between the proof mass and bump stops is a large contributing factor to the stiction force, altering the shape and geometry (e.g., curved/angled surfaces) of the bump stop in order to reduce contact area (e.g., promoting point or line contacts instead of larger surface contacts) is beneficial for providing release or lift points for the non-regular movements of the proof mass described herein. For example, through the use of square-arrayed bump stops 712, rectangular-notched bump stops 706, and diamond-shaped bump stops 708, it is possible to provide release or lift surfaces such as at corners or about axes with minimal contact area.

Choosing bump stops with non-rectangular geometries may synergize with the electrostatic forces generated by the anti-stiction electrodes in order to more effectively release the stuck proof mass. For example, an ovular bump stop 702 may be used for any MEMS accelerometer including anti-stiction electrodes, regardless of the direction of the applied electrostatic force on the proof mass, as this ovular shape reduces surface area in all directions relative to its similarly-sized rectangular-shaped counterparts. However, arch-shaped bump stops 704 may be able to synergize better with particular placements of anti-stiction electrodes within the MEMS accelerometer. For example, placing anti-stiction electrodes in such a location as to apply an electrostatic force perpendicular to the spatial line of symmetry of the arch-shaped bump stop 704 would promote the removal of the stuck proof mass in a direction where less surface-to-surface contact would exist. Moreover, switching from an arch-shaped bump stop 704 to a chevron-shaped with rounded corners bump stop 710, would provide different stiction release characteristics based on a decreased surface area of the bump stop. It is understood that the examples of FIG. 7 are provide as example embodiments, the bump stops within the MEMS accelerometer may have a number of different configurations, shapes, designs, and geometries in order to reduce the stiction force.

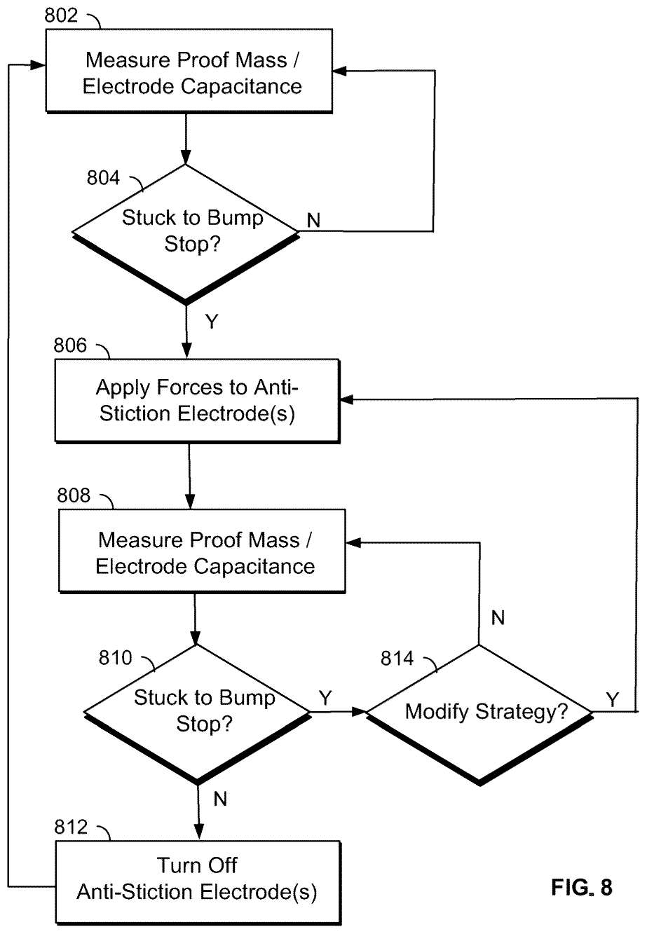

FIG. 8 depicts exemplary steps of a method of releasing a stuck proof mass from a bump stop using anti-stiction electrodes in accordance with an embodiment of the present disclosure. The usual functioning of MEMS accelerometers may consist of moments where the proof mass becomes stuck to one of the bump stops (or multiple bump stops) within its vicinity after an extreme external force is applied to the system. Although particular steps are depicted in a certain order, steps may be removed, modified, and substituted. Further, additional steps (and the order of those steps) may be added in certain embodiments.

Processing starts at step 802, where the location of the proof mass is monitored such as by monitoring a capacitance between the proof mass and a sense electrode. External forces acting on the MEMS accelerometer will cause a movement of the proof mass relative to the sense electrodes, resulting in change in the measured capacitance within the parallel-plate capacitator system when the MEMS accelerometer is operating properly. With the help of the sense springs attached to the proof mass, a restoring force may bring the proof mass back to its resting position and steady-state capacitance under normal conditions.

Proceeding to step 804, it is determined whether the proof mass is stuck to a bump stop. Under normal working conditions, the restoring force provided by the sense springs is able to overcome any stiction forces that may be encountered during the movement of the proof mass. The capacitance levels are transiently altered during the movement of the proof mass and return to steady-state values when the proof mass is returned to its original position. The proof mass is not stuck to the bump stop and normal functioning of the MEMS accelerometer continues. In this case, the process may proceed back to step 802. However, after an extreme external force is applied to the device, a collision between the proof mass and bump stops may cause contact between the proof mass and the bump stop, resulting in stiction forces greater than the restoring force provided by the sense springs, thus preventing the return of the proof mass to its resting position and the capacitance back to steady-state values. The measurement of this semi-permanent change in capacitance levels indicates the proof mass is stuck to the bump stop and anti-stiction forces may need to be applied. If the proof mass is stuck to the bump stop, processing continues step 806.

At step 806, one anti-stiction electrode or multiple anti-stiction electrodes are activated to facilitate the removal of the proof mass from the surface of the bump stop by applying forces that are not along the axis of contact between the proof mass and bump stop. The restoring force of the sense springs, in conjunction with irregular (e.g., non-parallel and/or non-perpendicular) electrostatic force generated at the anti-stiction electrodes, may be sufficient to overcome the stiction forces sticking the proof mass to the bump stops or partially overcome the stiction force such that springs have adequate force to complete the release from the bump stop. The process may proceed to step 808.

At step 808, after application of the forces by the anti-stiction electrodes, the proof mass is again monitored to determine whether it is stuck to the proof mass, similar to step 802 above. Once this measurement is performed, processing continues to step 810 at which it is determined whether the proof mass remains stuck to the bump stop, similar to step 804. If a change in capacitance indicates that the proof mass is no longer stuck to the bump stop and the process may continue to step 812. At step 812, any anti-stiction electrode that was activated is turned off. The MEMS accelerometer may function as usual with the process returning to step 802 to monitor for further stiction events.

In the event that at step 808 the capacitance levels did not change or return to steady-state values, then the proof mass is considered still stuck to the bump stop at step 810 and the process may proceed to step 814. In order to potentially overcome strong stiction forces that are causing the proof mass to stick to the bump stop, the applied electrostatic forces may be modified to more effectively dislodge the proof mass. For example, if at step 808 the capacitance levels are determined to slowly be moving towards the original steady-state values before stiction occurred, then a longer period of applied electrostatic force by the activated anti-stiction electrodes may be sufficient to dislodge the proof mass. The current strategy may stay in effect and the process may continue back to step 808. In cases where there is no significant change in capacitance values, as determined at step 808, the signal that is currently being applied to the proof mass is deemed to be ineffective for proof mass release and may be changed. The process may continue to step 806 where a new strategy of anti-stiction electrode activation may be employed. For example, different anti-stiction electrodes may be activated within the device to alter the directions of forces of the applied electrostatic force. As another example, the characteristics of the chirp signal may be altered to impact the applied potential, polarity, and/or frequency range at the anti-stiction electrodes.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A microelectromechanical system (MEMS) accelerometer, comprising:
a suspended spring-mass system comprising a proof mass, wherein the proof mass moves in a first mode along a first axis in response to an external linear acceleration;
a bump stop located below the proof mass along the first axis, wherein the proof mass is capable of moving along the first axis to contact and stick to the bump stop;
an anti-stiction electrode located adjacent to the proof mass that actuates the proof mass in a second mode along a second axis that is non-parallel to the first axis; and
processing circuitry configured to determine that the proof mass is stuck to the bump stop and to apply a signal to the anti-stiction electrode to cause a movement of the proof mass in the second mode at least until the proof mass releases from the bump stop.

2. The MEMS accelerometer of claim 1, wherein the suspended spring-mass system further comprises at least one sense spring, wherein the second mode is non-parallel to a torsional axis of the sense spring.

3. The MEMS accelerometer of claim 2, wherein the at least one sense spring applies a torsional force to the proof mass, wherein an application of the signal to the anti-stiction electrode applies a force to the proof mass that is non-parallel to the first mode, and wherein the release of the proof mass from the bump stop is based on a combination of the torsional force and the non-parallel force.

4. The MEMS accelerometer of claim 1, wherein, to determine that the proof mass is stuck to the bump stop, the processing circuitry monitors a sense signal from a sense electrode of the accelerometer to determine whether a threshold amplitude is exceeded for a threshold time.

5. The MEMS accelerometer of claim 1, wherein, to determine that the proof mass is stuck to the bump stop, the processing circuitry monitors a bump stop output signal at the bump stop to identify a threshold change in the bump stop output signal.

6. The MEMS accelerometer of claim 1, wherein the anti-stiction electrode comprises a plurality of anti-stiction electrodes located in a plane of the suspended spring-mass system, and wherein the movement of the proof mass in the second mode that is non-parallel to the first axis comprises an in-plane movement of the proof mass.

7. The MEMS accelerometer of claim 6, wherein the in-plane movement of the proof mass comprises a translational movement of the proof mass in the plane of the suspended spring-mass system.

8. The MEMS accelerometer of claim 6, wherein the in-plane movement of the proof mass comprises a rotational movement of the proof mass in the plane of the suspended spring-mass system.

9. The MEMS accelerometer of claim 1, wherein the anti-stiction electrode comprises a plurality of anti-stiction electrodes located in a second plane parallel to a first plane of the suspended spring-mass system, and wherein the movement of the proof mass in the second mode that is non-parallel to the first axis comprises a rocking movement about the second axis.

10. The MEMS accelerometer of claim 9, wherein the second axis is perpendicular to a third axis about which the proof mass rotates in response to the linear acceleration.

11. The MEMS accelerometer of claim 9, wherein the second axis is at an angle with respect to a third axis about which the proof mass rotates in response to the linear acceleration.

12. The MEMS accelerometer of claim 1, wherein the signal applied to the anti-stiction electrode comprises a periodic chirp signal.

13. The MEMS accelerometer of claim 12, wherein the processing circuitry is further configured to monitor whether the proof mass is released from the bump stop, and if the proof mass is not released from the bump stop, modify a signal characteristic of the periodic chirp signal.

14. The MEMS accelerometer of claim 13, wherein the signal characteristic comprises one of an amplitude of the periodic chirp signal, a frequency range of the periodic chirp signal, or a time that the periodic chirp signal is active.

15. The MEMS accelerometer of claim 1, wherein the processing circuitry is further configured to monitor whether the proof mass is released from the bump stop, and if the proof mass is not released from the bump stop, modify a signal characteristic of the signal.

16. The MEMS accelerometer of claim 1, wherein the bump stop has a non-rectangular shape.

17. The MEMS accelerometer of claim 1, wherein the bump stop and the anti-stiction electrode are located on opposite sides of a third axis about which the proof mass rotates in response to the linear acceleration.

18. The MEMS accelerometer of claim 1, wherein the second axis is also non-perpendicular to the first axis.

19. A method of releasing a proof mass of microelectromechanical system (MEMS) accelerometer from a bump stop, comprising:
determining, by processing circuitry, that a proof mass is stuck to a bump stop, wherein the proof mass moves in a first mode in response to a linear acceleration in a direction of a first axis, wherein the bump stop is located below the proof mass along the first axis, and wherein the proof mass is capable of moving along the first axis to contact and stick to the bump stop; and
applying, by the processing circuitry in response to the determination that the proof mass is stuck to the bump stop, a signal to an anti-stiction electrode to cause a movement of the proof mass in a second mode at least until the proof mass releases from the bump stop, wherein the anti-stiction electrode is located adjacent to the proof mass at a location to cause a movement of the proof mass in the second mode about a second axis that is non-parallel to the first axis when the proof mass is actuated by the anti-stiction electrode.

20. A microelectromechanical system (MEMS) accelerometer, comprising:
a suspended spring-mass system comprising a proof mass, wherein the proof mass moves about a first axis in response to an external linear acceleration and in a direction of a second axis that is out-of-plane from the suspended spring-mass system in response to the linear acceleration;
a bump stop located below the proof mass along the second axis, wherein the proof mass is capable of moving along the second axis to contact and stick to the bump stop;
an anti-stiction electrode located adjacent to the proof mass that actuates the proof mass in a second mode along a third axis that is non-parallel to the first axis and the second axis; and
processing circuitry configured to determine that the proof mass is stuck to the bump stop and to apply a signal to the anti-stiction electrode to cause a movement of the proof mass in the second mode at least until the proof mass releases from the bump stop.
